(19) United States
(12) Patent Application Publication
(10) Pub. No.: US 2014/0001509 A1
(43) Pub. Date: Jan. 2, 2014

(54) OPTOELECTRONIC SEMICONDUCTOR DEVICE AND THE MANUFACTURING METHOD THEREOF

(71) Applicants: Yi-Hung Lin, Hsinchu (TW); Cheng-Hong Chen, Hsinchu (TW); Shih-Chang Lee, Hsinchu (TW)

(72) Inventors: Yi-Hung Lin, Hsinchu (TW); Cheng-Hong Chen, Hsinchu (TW); Shih-Chang Lee, Hsinchu (TW)

(73) Assignee: EPISTAR CORPORATION, Hsinchu (TW)

(21) Appl. No.: 13/534,186

(22) Filed: Jun. 27, 2012

(51) Int. Cl. H01L 31/0224; H01L 31/18; H01L 33/40

(52) U.S. Cl. 257/99; 257/431; 438/22; 438/98; 257/E33.063; 257/E31.124

(57) ABSTRACT

An optoelectronic semiconductor device includes: an optoelectronic semiconductor stack including an upper surface; and a metal electrode structure formed on the optoelectronic semiconductor stack, wherein the metal electrode structure comprises a side surface including oxidized metal formed by oxidizing the metal electrode structure.

### TECHNICAL FIELD

The application relates to an optoelectronic semiconductor device and the method for manufacturing the optoelectronic semiconductor device.

### DESCRIPTION OF BACKGROUND ART

Because of the shortage of the petroleum energy resource and the promotion of the environment protection, people continuously and actively study the art related to the replaceable energy and the regenerative energy resources in order to reduce the dependence of petroleum energy resource and the influence on the environment. The solar cell is an attractive candidate among those replaceable energy and the regenerative energy resources because the solar cell can directly convert solar energy into electricity. In addition, there are no harmful substances like carbon oxide or nitride generated during the process of generating electricity so there is no pollution to the environment.

The basic structure of a solar-cell element includes an optoelectronic stack, a front electrode formed on the upper surface of the optoelectronic stack, and a back electrode formed on the bottom surface of the optoelectronic stack. Furthermore, for receiving most solar light, the upper surface of the optoelectronic stack may be covered by an anti-reflecting layer.

The solar-cell element can further connect to a base via a bonding layer to form a light-absorbing device. In additional, the base can further include at least a circuit to electrically connect to the electrode of the solar cell element via a conductive structure such as metal wire.

### SUMMARY OF THE DISCLOSURE

An optoelectronic semiconductor device includes: an optoelectronic semiconductor stack including an upper surface; and a metal electrode structure formed on the optoelectronic semiconductor stack, wherein the metal electrode structure comprises a side surface including oxidized metal formed by oxidizing the metal electrode structure.

A method for manufacturing an optoelectronic semiconductor device includes steps of: providing an optoelectronic semiconductor stack comprising an upper surface; forming a metal electrode structure including a side surface and having a pattern on the optoelectronic semiconductor stack; and oxidizing the side surface of the metal electrode structure to form an oxidized metal region.

### BRIEF DESCRIPTION OF THE DRAWINGS

FIGS. 1A to 1H show a method for manufacturing an optoelectronic semiconductor device in accordance with a first embodiment of the present application.

FIG. 2 shows a schematic diagram of an optoelectronic semiconductor device in accordance with a second embodiment of the present application.

### DETAILED DESCRIPTION OF PREFERRED EMBODIMENTS

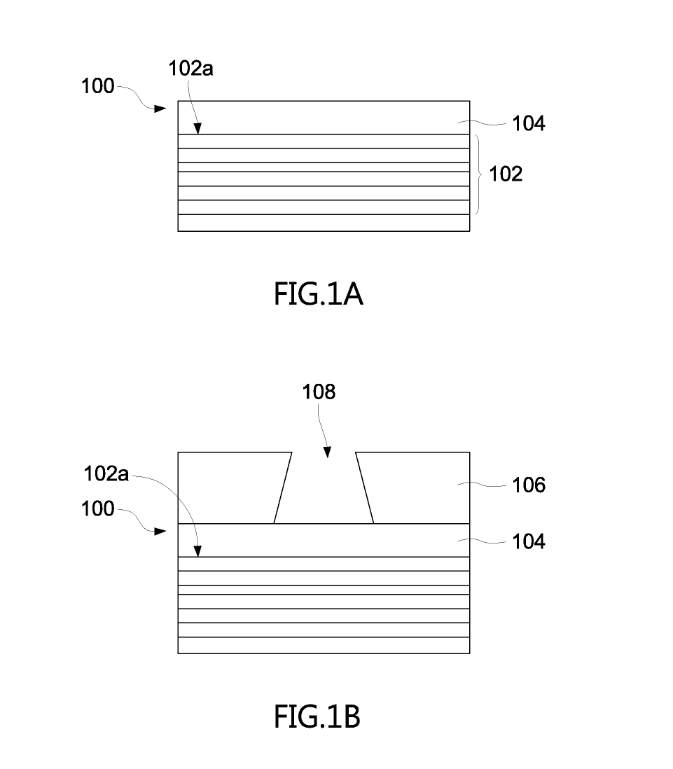

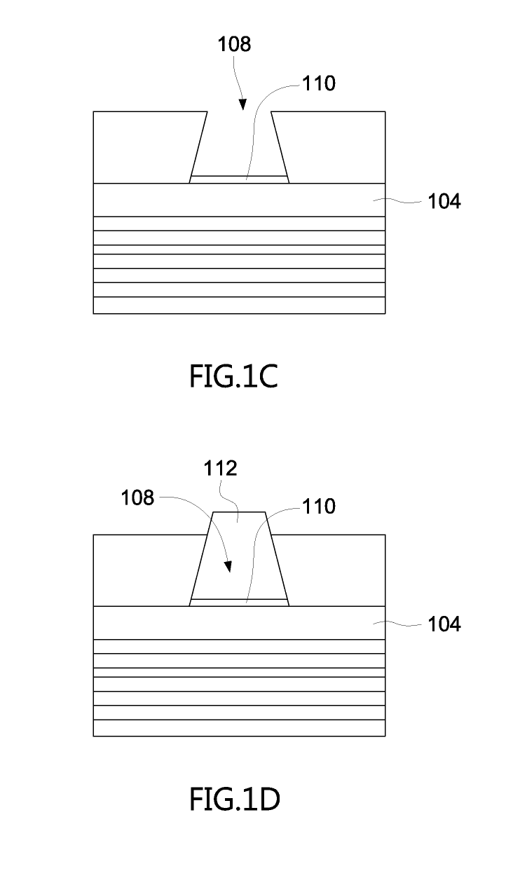

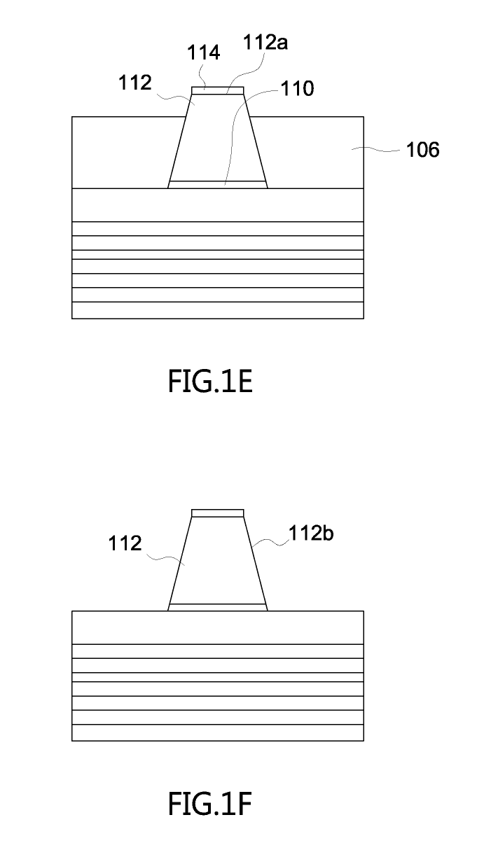

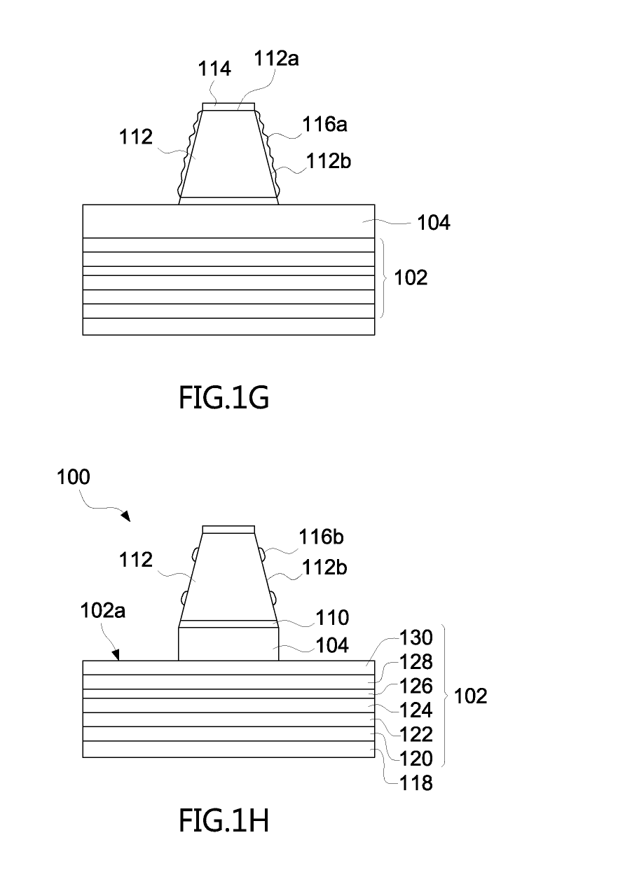

As shown in FIGS. 1A to 1H, a method for manufacturing an optoelectronic semiconductor device in accordance with a first embodiment of the present application is disclosed. Referring to FIG. 1A, providing an optoelectronic semiconductor device 100 including: an optoelectronic semiconductor stack 102 having an upper surface 102a; and a first contact layer 104 formed on the upper surface 102a. The first contact layer 104 is a semiconductor contact layer and can be formed on the upper surface 102a of the optoelectronic semiconductor stack 102 by epitaxial growth.

Referring to FIG. 1B, a mask layer 106 is formed on the first contact layer 104, and an opening 108 having a pattern is formed through the mask layer 106 to expose a partial region of the first contact layer 104. The mask layer 106 can be a photo resistor.

Referring to FIG. 1C, a second contact layer 110 is formed on the first contact layer 104 corresponding with the opening 108. The material of the second contact layer 110 can be metal, and to be more specific, the second contact layer 110 can be Au. The second contact layer 110 can be formed by deposition, electrical plating or chemical plating, and so on.

Referring to FIG. 1D, a step for forming a metal electrode structure 112 on the second contact layer 110 is disclosed. The material of the metal electrode structure 112 can be Ag. The metal electrode structure 112 fills the opening 108 to have the same pattern with that of the opening 108. The metal electrode structure 112 can be formed by deposition, electrical plating or chemical plating, and so on.

Referring to FIGS. 1E and 1F, a protecting-metal layer 114 can be formed on the upper surface 112a of the metal electrode structure 112 as shown in FIG. 1E to prevent the upper surface from being oxidized in later processes. The material of the protecting-metal layer 114 can be Au. After forming the protecting-metal layer 114, the mask layer 106 is removed to expose the side surface 112b of the metal electrode structure 112 as shown in FIG. 1F.

Referring to FIG. 1G, the side surface 112b of the metal electrode structure 112 is oxidized to form an oxidized metal region 116a by soaking the metal electrode structure 112 in a halogen compound solution (not shown) together with the optoelectronic semiconductor stack 102, and the oxidized metal region 116a can include AgCl, AgF, AgBr, or other metal-halogen compound. Furthermore, the metal electrode structure 112 can be soaked in a solution including S, and the oxidized metal region 116a can include Ag₂S. After the side surface 112b is oxidized, the first contact layer 104 can be removed by an etching solution according to the pattern of the metal electrode structure 112, and the oxidized metal region 116a serves as a sacrificed layer to be simultaneously removed by the etching solution for removing the first contact layer 104.

Referring to FIG. 1H, a process for removing the first contact layer 104 according to the pattern of the metal electrode structure 112 is disclosed. The first contact layer 104 can be GaAs and can be removed by an etching solution containing H₂O₂, and after removing the first contact layer 104 not under the metal electrode structure 112, an oxidized metal 116b can be still detectable on partial regions of the side surface 112b, and the upper surface 102a of the optoelectronic semiconductor stack 102 can be exposed. The optoelectronic semiconductor device 100 of the present embodiment can be a solar-cell device and can include: a back electrode 118; the optoelectronic semiconductor stack 102 including: a conductive substrate 120 having a first junction formed on the back electrode 118, wherein the first junction is formed by doping two different materials in the conductive substrate 120; a first tunnel junction 122 formed on the conductive substrate 120; a first semiconductor layer 124 formed on the first tunnel junction 122, wherein the first semiconductor layer 124 has a second junction formed by sequentially doping two different materials therein during epitaxial growth process; a second tunnel junction 126 formed on the first semiconductor layer 124; and a second semiconductor layer 128 formed on the second tunnel junction 126, wherein the second semiconductor layer 128 has a third junction formed by sequentially doping two different materials therein during epitaxial growth process. The first junction, second junction and third junction include p-n junction or p-i-n junction. The material of the conductive substrate 120 can be Ge, and the material of the first semiconductor layer 124 can be GaAs, and the material of the second semiconductor layer 128 can be InGaP. The first tunnel junction 120 and the second tunnel junction 126 can include InGaAs/AlGaInAs junction and InGaP/AlGaInAs junction, respectively.

The optoelectronic semiconductor device 100 further includes a light-absorbing layer 130 on the second semiconductor layer 128 for receiving more light from outside, and the material of the light-absorbing layer 124 can include AlInP.

The first contact layer 104 forms between the light-absorbing layer 130 and the second contact layer 110, and the second contact layer 110 and the first contact layer 104 form a contact structure. The metal electrode structure 112 being the front electrode of the solar-cell device (optoelectronic semiconductor device 100) forms on the second contact layer 110. An anti-reflecting layer (not shown) can be formed on the light-absorbing layer 130 to enhance the light-transmission from outside.

Conventionally, the material of front electrode of solar-cell device is Au, however the cost of Au has been largely raised year by year, and some solar-cell suppliers turned to Ag for replacing Au for the material of front electrode of solar-cell device. However, for the Ag electrode structure, Ag may be partially etched by the etching solution for etching the semiconductor contact layer, therefore the semiconductor contact layer may not be completely etched away so as to cause electrical failure of the solar-cell device. By the manufacturing method of the present application, the oxidized metal region formed on the electrode structure can prevent the etching solution for removing the first contact layer from directly contacting the electrode structure to avoid the drawbacks of the electrode structure of the conventional optoelectronic device.

The optoelectronic semiconductor device 100 is not restricted to be a solar-cell device, and can also be a light-emitting device, and the optoelectronic semiconductor stack 102 can be a light-emitting stack.

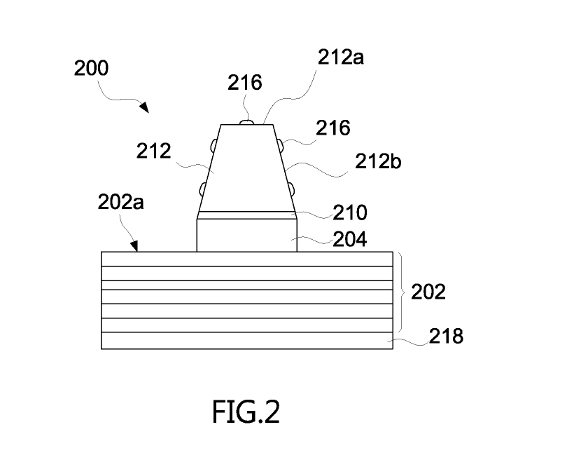

As shown in FIG. 2, an optoelectronic semiconductor device in accordance with a second embodiment of the present application is disclosed. The optoelectronic semiconductor device 200 includes: a back electrode 218; an optoelectronic semiconductor stack 202 including an upper surface 202a; a first contact layer 204 formed on the upper surface 202a; a second contact layer 210 formed on the first contact layer 204; and a metal electrode structure 212 formed on the second contact layer 210, wherein an oxidized metal 216 formed by oxidizing the metal electrode structure 212 can be detected on the side surface 212b of the metal electrode structure 212, and the oxidized metal 216 can be randomly detectable on the upper surface 212a of the metal electrode structure 212. The difference between the first embodiment and the second embodiment is that in the second embodiment there is no protecting-metal layer formed on the upper surface 212a of the metal electrode structure 212, and the upper surface 212a can be oxidized together with the side surface 212b.

Although the present application has been explained above, it is not the limitation of the range, the sequence in practice, the material in practice, or the method in practice. Any modification or decoration for present application is not detached from the spirit and the range of such.

What is claimed is:

1. An optoelectronic semiconductor device comprising:
an optoelectronic semiconductor stack comprising an upper surface; and
a metal electrode structure formed on the optoelectronic semiconductor stack, wherein the metal electrode structure comprises a side surface comprising oxidized metal formed by oxidizing the metal electrode structure.

2. The optoelectronic semiconductor device according to claim 1, wherein the metal electrode structure comprising Ag or Ag alloy.

3. The optoelectronic semiconductor device according to claim 2, wherein the oxidized metal comprises metal-halogen compound.

4. The optoelectronic semiconductor device according to claim 3, wherein the metal-halogen compound comprises AgCl, AgF, or AgBr.

5. The optoelectronic semiconductor device according to claim 2, wherein the oxidized metal comprises Ag₂S.

6. The optoelectronic semiconductor device according to claim 1, further comprising a first contact layer formed on the optoelectronic semiconductor stack, and a second contact layer formed between the first contact layer and the electrode structure.

7. The optoelectronic semiconductor device according to claim 6, wherein the first contact layer comprises semiconductor and the second contact layer comprises metal.

8. The optoelectronic semiconductor device according to claim 7, wherein the first contact layer comprises GaAs, and the second contact layer comprises Au.

9. The optoelectronic semiconductor device according to claim 1, wherein the metal electrode structure comprises an upper surface comprising a protecting-metal layer thereon.

10. The optoelectronic semiconductor device according to claim 1, wherein the oxidized metal is formed on partial regions of the side surface of the metal electrode structure.

11. The optoelectronic semiconductor device according to claim 1, wherein the metal electrode structure comprises an upper surface comprising the oxidized metal.

12. The optoelectronic semiconductor device according to claim 1, wherein the optoelectronic semiconductor stack comprises solar-cell stack or light-emitting stack.

13. A method for manufacturing an optoelectronic semiconductor device comprising steps of:
providing an optoelectronic semiconductor stack comprising an upper surface;
forming a metal electrode structure comprising a side surface and having a pattern on the optoelectronic semiconductor stack; and
oxidizing the side surface of the metal electrode structure to form an oxidized metal region.

14. The method for manufacturing an optoelectronic semiconductor device according to claim 13, further comprising forming a first contact layer on the optoelectronic semiconductor stack, and the metal electrode structure is formed on the first contact layer.

15. The method for manufacturing an optoelectronic semiconductor device according to claim 14, further comprising forming a second contact layer on the first contact layer before forming the metal electrode structure.

16. The method for manufacturing an optoelectronic semiconductor device according to claim 15, further comprising removing the first contact layer according to the pattern of the metal electrode structure.

17. The method for manufacturing an optoelectronic semiconductor device according to claim 16, wherein the oxidized metal region is removed during removing the first contact layer.

18. The method for manufacturing an optoelectronic semiconductor device according to claim 13, further comprising forming a protecting-metal layer on the upper surface of the metal electrode structure before oxidizing the side surface of the metal electrode structure.

19. The method for manufacturing an optoelectronic semiconductor device according to claim 13, further comprising forming a mask layer comprising an opening for defining the pattern of the metal electrode structure before forming the metal electrode structure.

20. The method for manufacturing an optoelectronic semiconductor device according to claim 19, wherein the mask layer is a photo resistor.
